(19) United States
(12) Patent Application Publication
(10) Pub. No.: US 2013/0081676 A1
(43) Pub. Date: Apr. 4, 2013

(54) Multi-Purpose Solar Panel

(71) Applicant: SCUINT CORPORATION, Austin, TX (US)

(72) Inventor: Steven B. Snidow, Austin, TX (US)

(73) Assignee: SCUINT CORPORATION, Austin, TX (US)

(21) Appl. No.: 13/633,109

(22) Filed: Oct. 1, 2012

Related U.S. Application Data
(60) Provisional application No. 61/542,266, filed on Oct. 2, 2011.

(51) Int. Cl. H01L 31/048; H01L 31/18

(52) U.S. Cl. 136/251; 29/890.033

(57) ABSTRACT

A multi-purpose solar panel providing for electricity generation and for additional digital and analog services that may be provided for one end user, other third party end users and/or the community at large.

### CROSS-REFERENCE TO RELATED APPLICATIONS

This application claims the benefits of the filing of U.S. Provisional Patent Application Ser. No. 61/542,266, entitled Multi-Purpose Solar Panel, filed Oct. 2, 2011 and the specification thereof is incorporated herein by reference.

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISK APPENDIX

Not Applicable.

### TECHNICAL FIELD

The present invention is in the technical field of photovoltaic devices. More particularly, the present invention is in the technical field of solar panels.

### BACKGROUND OF THE INVENTION

Conventional photovoltaic solar panels are made for the express and sole purpose of electricity generation though solar gain with the conventional design of solar panels to be, essentially, comprised of a backing plate, an array of interconnected solar cells, electrical components, a flat and transparent glass cover that, together, are held within a weatherproof frame. Each panel will consist of a number of solar cells that are laid flat to form a plane and that are held between the backing plate and the glass cover. Tension is often achieved through use of the frame holding all the elements together and in place. Each individual solar panel is oriented on a fixed, or adjustable, mounting system for the purpose of maximizing, for a particular site, its solar gain and, therefore, its electricity generation potential. Placement of the solar panel, or array, is critical to solar gain and results in the placement of arrays away from skyline objects that may interfere with solar gain such as trees and tall buildings. This necessity often results in the placement of solar panels, or array, in open areas, such as a plain or desert, or on rooftops.

Current solar panels are devised to provide for the single action of electrical current generation and that may be attenuated through add-on or integrated devices, such as micro-inverters or impedance matching, to improve overall electrical current delivery. However, the single utility of such panels creates numerous problems to be resolved and that can be seen in various ways through the broader solar market. The typical problem realized with most solar panels, and larger solar installations, is the cost borne by the end user(s) that is directly, and indirectly, driven from the technologies used for the fabrication and installation of solar panels and, as well, the fact that such costs are to be offset by only the realization of energy production. The manifestation of this core issue is seen through the relatively slow adoption of photovoltaic technologies by consumers and the relatively large proportion of solar company bankruptcies.

Small scale solar panels, or cells, can also be purposed as an energy source and embedded for direct use into functional products such as handheld calculators. In such embodiment, solar panels (cells) are configured in a one-to-one relationship with the functional product and are thereby so limited in their application.

The main characteristics of solar panels, as described above, are seen through the below prior art and that also acts to demonstrate the primary constraint, or problem, of utilizing solar panels (cells) as an panel-level, array-level or a product-specific energy source.

For example, U.S. Pat. No. 4,167,644 (Kurth et al.; 1979) is a solar cell module and teaches us that many current and contemporary solar panel designs commercially available on the market are designs utilizing the same principles as explained by Kurth et al., and that, primarily, consist of a plurality of flat solar cells interconnected and a flat substrate and covered with a transparent cover to affect the principle purpose of electricity generation.

U.S. Pat. No. D600,200 (from Dimov et al.; 2009) is a solar panel arrangement that teaches us an approach to solar panels in which the standard, rectangular, panel shape is reconfigured into a beehive-like configuration of three panels and that utilizes the same flat panel structure and resulting in only the one purpose of electricity generation.

U.S. Pat. No. D618,166 (Sanoner; 2010) is a solar panel for light and teaches us one current state of a small solar panel used as an integrated component into another object, such as a walkway light, that demonstrates the integration of a solar panel into a standalone armature and with the end purpose of light generation derived through a one-to-one relationship of the solar cell (panel) and the light.

U.S. Pat. No. 7,492,120 (Benn et al.; 2009) is a mobile solar generator that may be considered multi-purpose in application (e.g., used as a power source for construction, used for lighting, etc.) but that teaches us that the invention, itself, is comprised of, in addition to structural components, flat solar panels that have the sole purpose of electricity generation.

U.S. Pat. No. 5,898,932 (Zurlo et al.; 1999) is a portable cellular phone with integral solar panel that teaches us the integration of a solar panel (cell) into a cellular handset device and showing a common practice of using the electricity generating capability of solar panels (cells) as a add-on capability to an existing technology and limited to a one-to-one relationship between the solar panel (cells) and the cellular phone.

U.S. Pat. No. 7,962,042 (Deas; 2011) is a method and system for delivering broadband services and that teaches us a current design of communication services, such as broadband, being delivered into a neighborhood but powered by commercially available electricity delivered by the existing, alternating current-based, grid. This patent also demonstrates the utility of providing digital services, such as ultrawide band communications, from a common platform to multiple, nearby, end users as well as the need to convert the alternating current (AC) from the grid to direct current (DC) for the electronic component(s) providing the broadband service(s).

### SUMMARY OF THE INVENTION

The present invention is a photovoltaic device configured to provide for integrated (e.g., co-located) services (in singular or in plural) to, or in addition to, the primary purpose of a solar panel to generate electrical current. Additional purposes (services) may include, but are not necessarily limited to, wireless interconnection, Internet protocol, emergency radio, integrated energy storage or other electrical or electronic service.

The invention is further a method of making a final weatherproofed product from the photovoltaic active components and co-located electrical and/or electronic components of the invention and comprising the steps of: photovoltaic cell testing/acceptance, electrical/electronic component testing/acceptance; photovoltaic cell alignment; photovoltaic cell tabbing; electrical/electronic service alignment; electrical/electronic service mounting; photovoltaic cell mounting; electrical/electronic interconnection/testing; back substrates mounting; frame enclosure; transparent cover mounting; sealing; external electrical component mounting and final test.

The primary objective of the present invention is to provide for the broader installation of solar panels and the electricity generation thereof by creating a common service platform consisting of photovoltaic technology and other electrical and/or electronic services so combined to provide for an overall more cost effective experience to one, or more, end users.

The primary advantage of the present invention is that by providing for co-located services within one, or more, solar panels, the same essential cost structure of manufacture, delivery and installation of solar panels is realized but that total cost may now be offset more effectively through the presence and use of the additional co-located services.

An additional advantage of the present invention is that by co-locating both the direct current (DC) electrical generation from the solar panel's photovoltaic active elements with the DC electrical consumption of co-located electrical and/or electronic devices, the need for additional devices, such as inverters that change DC to alternating current (AC), can be reduce or avoided and with the recognition that such AC devices typically result in the loss of electricity from the DC-to-AC conversion and thereby increasing the energy efficiency of the present invention.

Another advantage of the present invention is that by co-locating certain services, such as wireless communications, with the primary purpose of the solar power for electricity generation and that, typically, requires the solar panel(s) to be in an elevated position, the present invention can be more effectively utilized to provide co-located wireless communication services to the benefit of multiple, including third, parties located nearby or as part of a larger wireless and/or cellular infrastructure.

Still another advantage of the present invention is that additional co-located services, or service devices, may include electrical and/or electronic services not currently enjoyed by one, or more, end users including emergency and weather notifications, first responder communications, data/media storage and similar services for the overall benefit of the end user(s).

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWING

FIG. 1 is an isometric view of a typical solar panel;

FIG. 2 is an isometric view of one representation of the present invention;

FIG. 3 is an isometric view of an alternative representation of the present invention;

FIG. 4 is an isometric view of a second alternative representation of the present invention;

FIG. 5 is a simplified rendition of a typical house that includes application of the present invention and representation of co-located electronic services;

FIG. 6 is an overhead view of a typical residential neighborhood indicating one representation of co-located electronic services;

FIG. 7 is a simplified diagram explaining the co-located electrical services.

### DETAILED DESCRIPTION OF THE INVENTION

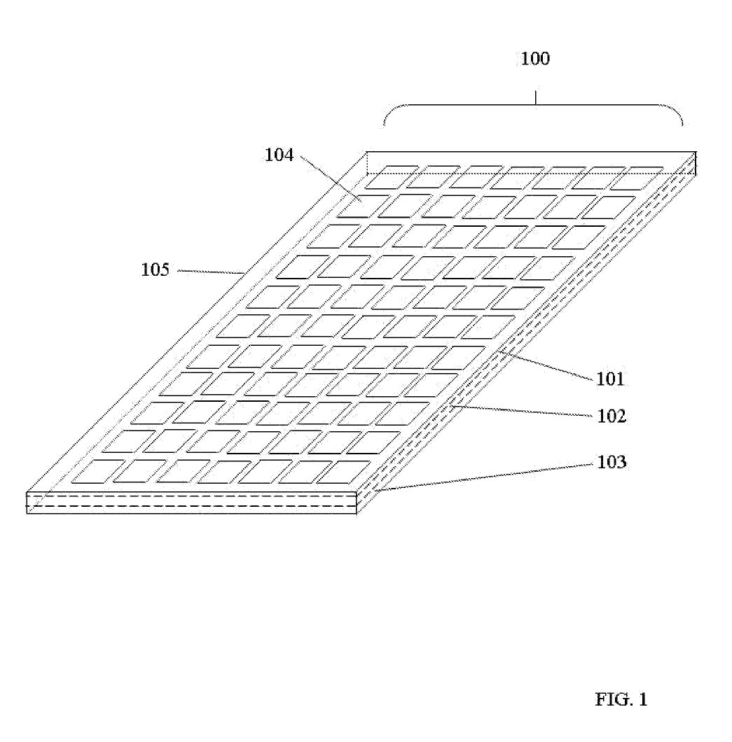

Referring now to FIG. 1, a typical solar panel, or photovoltaic device, 100 is shown to be comprised of a transparent cover 101, a middle section 102 comprised of a plurality of photovoltaic solar cells 104 that rest on back substrate 103. These components are bounded by structural frame 105 which is understood to encase the listed components on four sides.

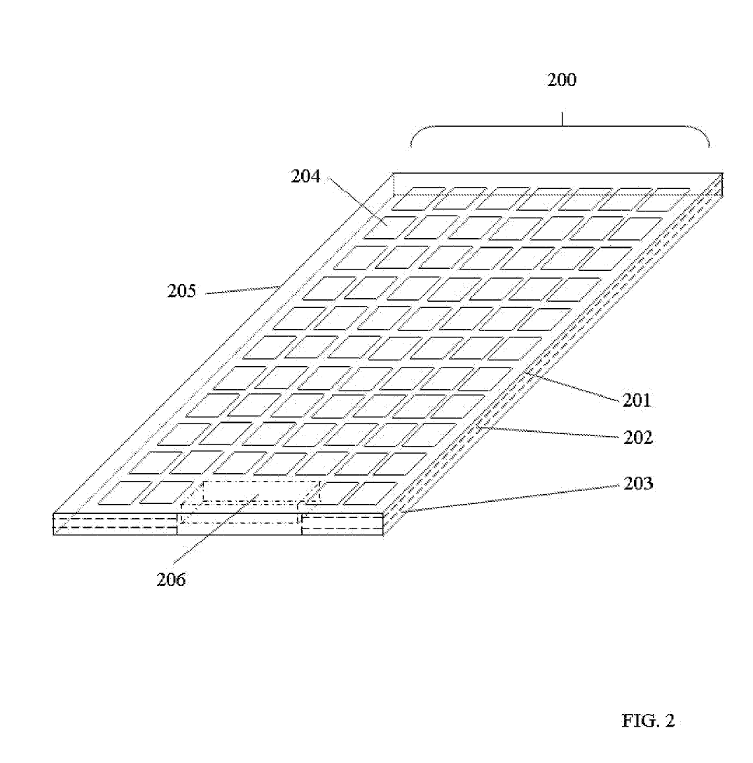

Referring in more detail to the present invention in FIG. 2, a modified photovoltaic device 200 is shown to be comprised of a transparent cover 201, a middle section 202 comprised of a plurality of photovoltaic solar cells 204 that rest on back substrate 203. These components are bounded by structural frame 205 which is understood to encase the listed components on four sides. Co-located electronic service device 206 is shown at the end of photovoltaic device 200 and should be understood to be enclosed within the structure of photovoltaic device 200. Co-located service device 206 should be understood to represent any one electronic service device such as, but not limited to, wireless communication, digital storage, sensor devices, computing devices or other, similar, digital or analog devices.

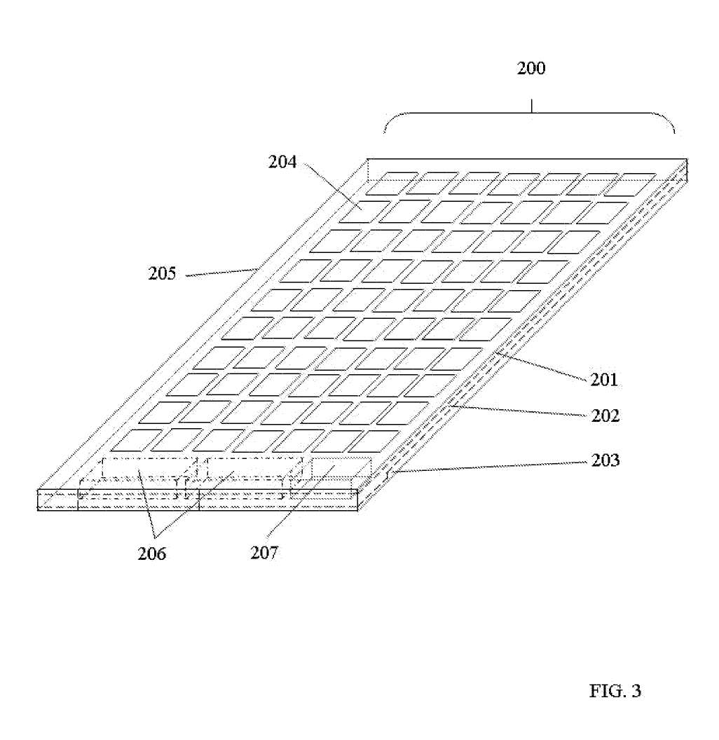

Referring now to FIG. 3, an alternative representation of the present invention is shown with modified photovoltaic device 200 is shown to be comprised of a transparent cover 201, a middle section 202 comprised of a plurality of photovoltaic solar cells 204 that rest on back substrate 203. These components are bounded by structural frame 205 which is understood to encase the listed components on four sides. Two co-located electronic service devices 206 are shown at the end of photovoltaic device 200 and should be understood to be enclosed within the structure of photovoltaic device 200. Co-located electronic service devices 206 should be understood to represent any one electronic service device such as, but not limited to, wireless communication, digital storage, sensor devices, computing devices or other, similar, digital or analog devices and, together, represent the possibility to co-locate multiple such services and in various combinations. Additionally, electrical service device 207 is shown at the end of photovoltaic device 200 and should also be understood to be enclosed within the structure of photovoltaic device 200. Co-located electrical service 207 should be understood to be a DC-to-DC converter, rechargeable battery or other, similar, device.

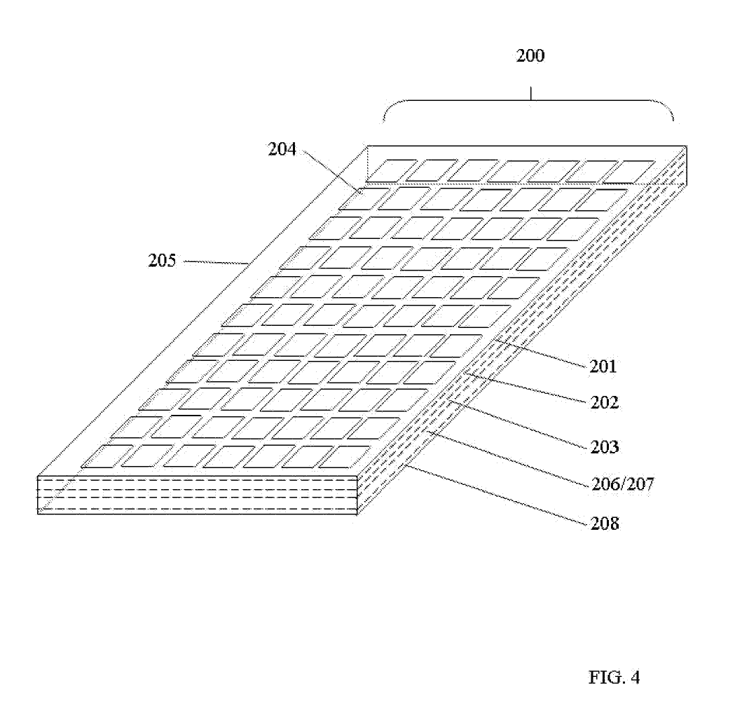

Referring now to FIG. 4, an alternative approach to co-locate electronic services 206 and electrical services 207 into modified photovoltaic device 200 is shown wherein photovoltaic device 200 is structured in layers consisting of a transparent cover 201, a middle section 202 comprised of a plurality of photovoltaic solar cells 204 that rest on back substrate 203. Below the layer of back substrate 203 is the service layer and that may be comprised of both electronic service devices 206 and electrical service devices 207 that are configured to fit within a broader structural frame 205 and that also are secured above a second back substrate 208 and such that electronic service devices 206 and electrical service devices 207 are held between the two substrates. These components are bounded by structural frame 205 which is understood to encase the listed components on four sides.

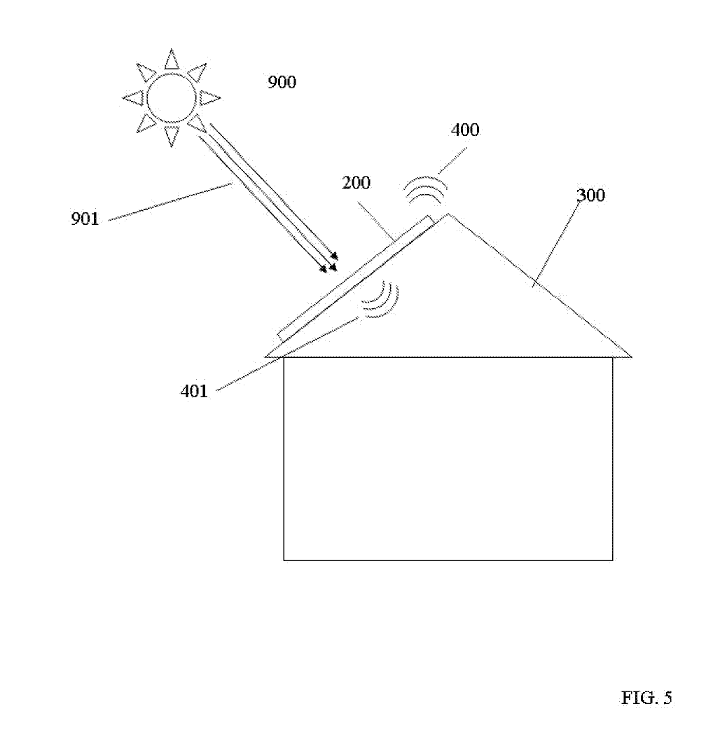

Referring now to FIG. 5, modified photovoltaic device 200 is shown to be situated on typical house 300. Modified photovoltaic device 200 is shown to be enabled with co-located wireless communication service represented by external wireless connection 400 and internal-to-the-residence wireless connection 401. For the purposes of clarification, modified photovoltaic is still enabled to gain sunlight 901 from the sun 900 and for the generation of electricity.

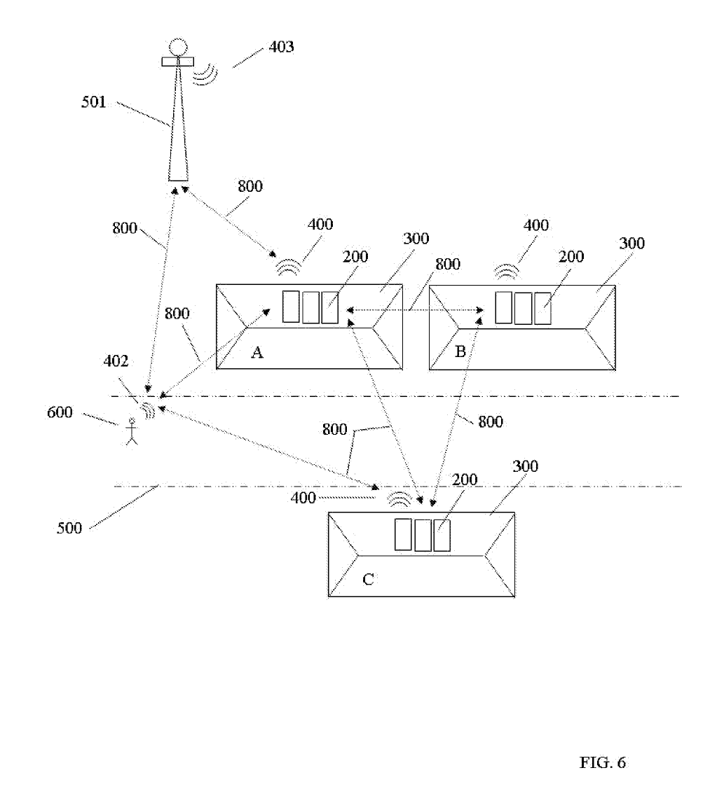

Referring now to FIG. 6, typical houses 300 are shown from an overhead perspective to be three separate houses A, B and C. Each typical house 300 has three modified photovoltaic devices 200 situated on it and each modified photovoltaic device 200 is enabled individually, or as an array, with external wireless communication connection 400. Typical residence C is separated from typical residence A and B by a common area, such as a road or sidewalk, 500. A third party, non-resident, end user 600 is enabled with a separate wireless device with wireless connection 402. Potential combinations of wireless connections between typical houses A, B, C and end user 600 are shown as two-way communication arrows 800. It should be understood that two-way communication arrows 800 are meant to represent not only the transmission of voice and media content but also data content, instruction and other typical forms of machine-to-machine wireless communication. Further communication is enabled through connection to cellular tower 501 with wireless communication connection 403 and indicating two-way communication arrows 800 shown between cellular tower 501, end user 600 and typical residence A.

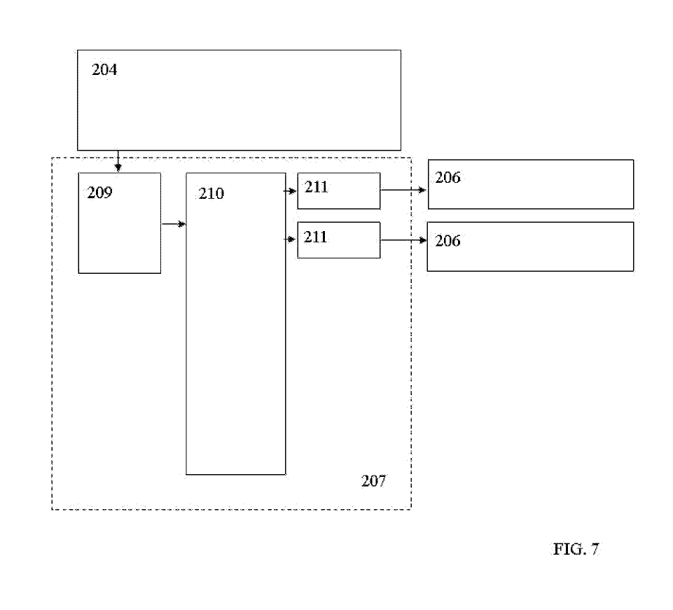

Referring now to FIG. 7, a basic and partial electrical diagram is shown to demonstrate the intent and utility of the co-located electrical services 207 shown in dashed box. As represented, the plurality of photovoltaic cells 204 create direct electrical current (DC) that is connected to a voltage regulator 209 that acts to condition the DC power to rechargeable battery 210. As needed, co-located electronic service devices 206 draw from rechargeable battery 210 DC power through DC-to-DC converters 211 that further condition the power. For the purposes of clarification, co-located electronic service devices 206 should be understood to be two different services and may represent one, or more, same or different, co-located electronic services. Further, DC-to-DC power converters 211 should be understood to represent one, or more, DC-to-DC power converters that are matched to one, or more, co-located electronic service devices 206 as dependent on those electronic service device's individual energy requirements. Further, co-located electrical service 207 may be understood to be comprised of one, or more, voltage regulator 209, rechargeable battery 210 or DC-to-DC converters 211 in singular or in various counts and combinations. For example, co-located electrical service may be comprised of only a rechargeable battery 210 or, by further non-limiting example, multiple rechargeable batteries 210 each with one, or more, corresponding DC-to-DC converters connected to one, or more, co-located electronic service devices.

The advantages of the present invention include, without limitation, co-located services to benefit end users, including community end users, by providing bundled services and/or the platform from which services can be provided that are not readily available to service providers today. Currently, solar energy is relatively expensive and not readily adopted by commercial enterprise or residential consumers. Further, currently, solar energy production is limited in its revenue production by solar panels that rely on relatively expensive, flat, solar cells. By integrating additional services to solar panels, individually or mixed in an array, additional services can be provided to the commercial enterprise and/or residential consumers while also providing additional revenue to the supplying companies thus making ability to deliver and acceptance of solar energy production more likely by the public. The second-service(s) provided are particularly relevant to electronic (i.e., powered) services such as wireless communications and the continuing build-out of wireless infrastructures to include, but not limited to, femtocell, picocell, digital radio and related concepts (services).

In broad embodiment, the present invention is a component of an integrated infrastructure allowing for multiple services to benefit end users and the community at large.

### DESCRIPTION OF THE PREFERRED EMBODIMENTS

### Best Modes for Carrying Out the Invention

The present invention provides for a new form of photovoltaic device that combines one, or more, co-located services to the primary function of electricity generation through photovoltaic action and a resulting method to make the new device. The functions that may be provided by the present invention are premised on photovoltaic electricity generation with the addition of co-located services that include, but are not limited to, cellular communication, wireless communication, satellite communication, digital data and/or media storage, computing, digital and/or analog sensors, electricity storage, electricity conditioning and other manipulation of electricity. The present invention is limited in function by physical parameters such as weight and dimensions and that the present invention, in addition to the primary function of photovoltaic action, may include any combination of co-located services that may be contained within the device's physical constraints. The present invention's functionality may be expanded by combination to other, similarly enabled, photovoltaic devices that are populated with other, and additional, co-located services that may then together comprise a combined service platform.

The present invention is comprised first of photovoltaic cells and second of co-located, electrical or electronic, services. The photovoltaic cells may be comprised of one, or more, different cell types, shapes and/or configurations including, but not limited to, silicon-based and thin films-based photovoltaic cells. The photovoltaic cells may be electrically interconnected in series and/or parallel to form a functional solar panel and that then may also be electrically interconnected to other solar panel devices to form a solar panel array. The present invention is comprised further of co-located services that are either electrical or electronic. Electrical services may include various combinations electricity conditioning and/or energy storage devices. Electronic services may include various combinations of printed circuit board-based devices populated with individual electrical components, such as resistors, capacitors, microchips, and other components, to provide a hardware device onto which various software may also be loaded and to affect the basis for such co-located electronic service(s).

The present invention preferably combines the electricity generation of the photovoltaic panel(s) with the widest implementation and use of co-located services given that such broader use of co-located services acts to address the growing demand of consumer and business end users for increased communication, data storage and affordable energy with the ancillary benefit of a renewable energy source. A preferred embodiment of the present invention includes sufficient direct current electrical generation capacity to provide power to all co-located service devices including electricity storage devices, and surplus electricity generation to be utilized in alternating current applications such as to power other electrical devices within a domicile or to be delivered into the larger electrical grid. This preferred embodiment includes also cellular communication services to enhance the cellular connection of the domicile as a primary user but also nearby cellular users; a wireless router for domicile use, data/media storage; sensor devices; computing devices and may also include satellite communications. Alternative embodiments may include one, or more, of such co-located services provided to one, or more, end users or co-located services that may be segregated and provided to different end users.

Because the present invention results in a multi-service platform, the present invention can be used as a substitute for other electronic devices typically located within a domicile such as a digital video recorder, mass storage device, wireless router, cable modem, computing devices and other, similar devices.

### INDUSTRIAL APPLICABILITY

The invention is further illustrated by the following non-limiting examples.

### Example 1

The present invention may include, in addition to electricity generation, co-located services such as those provided from femtocell, picocell or a combination of wireless cellular devices and that enable the present invention to also act as a cellular communications device for the benefit of one, or more, nearby users by providing improved cellular communication connection to a broader cellular infrastructure and that may result in increased bandwidth and improved quality of service for such end user(s) as well as an cellular infrastructure node utilized by cellular carriers.

### Example 2

The present invention may include, in addition to electricity generation, co-located services such as a wireless router, or Wi-Fi device, that may improve overall coverage to a domicile through its raised position on a roof and that may also provide for multi-channel and multi-user options thus providing an increased amount of wireless connectivity to multiple users and/or multiple wireless devices within one domicile affecting an overall higher quality of service to the end user(s).

### Example 3

The present invention may include, in addition to electricity generation, co-located services such as a digital media storage device that may be connected to computing and/or input device wirelessly or by wired convention. Such digital media storage device may act as a mass storage device for typical computing files created from common-use applications but may also act as a media content storage device similar to a digital video recorder or digital media storage device may act as a combination of storage devices and that may be accessible through the domicile only or through other means and act as a service such as the “cloud” services commonly provided by third party companies.

The preceding examples can be repeated with similar success by substituting the generically or specifically described parameters and/or operating conditions of this invention for those used in the preceding examples.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

I claim:

1. A photovoltaic device that provides at least one electronic services that are in addition to the primary purpose of generating electricity and where such generated electricity is delivered to external, non-photovoltaic, devices and where the photovoltaic device is comprised of:
a. One, or more, photovoltaic cells arranged and interconnected to provide the generation of electricity;
b. A transparent cover to provide light to the photovoltaic cells;
c. At least one co-located electronic service device;
d. A support structure to secure all photovoltaic device components;
e. An encasement to house the components of the photovoltaic device;
f. An external connection to mount the photovoltaic device onto a surface;

2. A photovoltaic device that provides at least one electrical service and at least electronic service that in addition to the primary purpose of generating electricity and where such generated energy is delivered to co-located electronic services through co-located electrical services and also to external, non-photovoltaic, devices and where the photovoltaic device is comprised of
a. One, or more, photovoltaic cells arranged and interconnected to provide the generation of electricity;
b. A transparent cover to provide light to the photovoltaic cells;
c. At least one co-located electrical service;
d. At least one co-located electrical service that is a rechargeable battery;
e. At least one co-located electronic service device;
f. A support structure to secure all photovoltaic device components;
g. An encasement to house the components of the photovoltaic device;
h. An external connection to mount the photovoltaic device onto a surface;

3. A photovoltaic device that provides at least one electrical service and at least electronic service that in addition to the primary purpose of generating electricity and where such generated energy is delivered to co-located electronic services through co-located electrical services and also to external, non-photovoltaic, devices and where the photovoltaic device is comprised of:
a. One, or more, photovoltaic cells arranged and interconnected to provide the generation of electricity;
b. A transparent cover to provide light to the photovoltaic cells;
c. At least one co-located electrical service;
d. At least one co-located electrical service that is a rechargeable battery;
e. At least one co-located electronic service device;
f. At least one co-located electronic service devices that is a digital media storage device;
g. A support structure to secure all photovoltaic device components;
h. An encasement to house the components of the photovoltaic device;
i. An external connection to mount the photovoltaic device onto a surface;

4. A photovoltaic device that provides at least one electrical service and at least electronic service that in addition to the primary purpose of generating electricity and where such generated energy is delivered to co-located electronic services through co-located electrical services and also to external, non-photovoltaic, devices and where the photovoltaic device is comprised of:
a. One, or more, photovoltaic cells arranged and interconnected to provide the generation of electricity;
b. A transparent cover to provide light to the photovoltaic cells;
c. At least one co-located electrical service;
d. At least one co-located electrical service that is a rechargeable battery;
e. At least one co-located electronic service device;
f. At least one co-located electronic service devices that is a digital computing device;
g. A support structure to secure all photovoltaic device components;
h. An encasement to house the components of the photovoltaic device;
i. An external connection to mount the photovoltaic device onto a surface;

5. A photovoltaic device comprised to provide one, or more, electronic functions for one, or more, end users in addition to the primary purpose of electricity generation and comprised to provide for the wireless communication between it and at least one other electronic wireless-enabled device;

6. A method of making a final photovoltaic device from the photovoltaic active components and co-located electrical and electronic components, the method comprising the steps of:
a. Photovoltaic cell testing and acceptance;
b. Electrical/electronic component testing and acceptance;
c. Photovoltaic cell alignment;
d. Photovoltaic cell tabbing;
e. Electrical service alignment;
f. Electrical service mounting;
g. Electronic service alignment;
h. Electronic service mounting;
i. Photovoltaic cell mounting;
j. Electrical and electronic interconnection and testing;
k. Back substrates mounting;
l. Frame enclosure mounting;
m. Transparent cover mounting;
n. Sealing of photovoltaic device;
o. External electrical component mounting;
p. Final test.
